(19) United States
(12) Patent Application Publication
(10) Pub. No.: US 2026/0072221 A1
(43) Pub. Date: Mar. 12, 2026

(54) OPTICAL INTERCONNECT WITH REFLECTOR STRUCTURE

(71) Applicants: Rowan Pocock, Sunnyvale, CA (US); Howard Rourke, Sunnyvale, CA (US); Jonathan Liu, Sunnyvale, CA (US); Robert Kalman, Sunnyvale, CA (US); Bardia Pezeshki, Sunnyvale, CA (US)

(72) Inventors: Rowan Pocock, Sunnyvale, CA (US); Howard Rourke, Sunnyvale, CA (US); Jonathan Liu, Sunnyvale, CA (US); Robert Kalman, Sunnyvale, CA (US); Bardia Pezeshki, Sunnyvale, CA (US)

(21) Appl. No.: 19/316,467

(22) Filed: Sep. 2, 2025

Related U.S. Application Data
(60) Provisional application No. 63/691,749, filed on Sep. 6, 2024.

(51) Int. Cl. G02B 6/42; H10H 20/01; H10H 20/841; H10H 20/853; H10H 20/854; H10H 29/24; H10H 29/85

(52) U.S. Cl. CPC G02B 6/4202; G02B 6/4249; H10H 20/034; H10H 20/0362; H10H 20/841; H10H 20/853; H10H 20/854; H10H 29/24; H10H 29/8508

(57) ABSTRACT

An optical interconnect may include an array of microLEDs driven to generate light based on data and/or clock signals, an array of photodetectors to receive the light and generate electrical signals corresponding to the data and/or clock signals, and optical fibers providing at least part of a pathway between the microLEDs and the photodetectors. A reflector structure for each of the microLEDs assists in coupling light from the microLEDs into the optical fibers. The reflector structure may be in the form of a compound parabolic concentrator (CPC).

### CROSS-REFERENCE TO RELATED APPLICATIONS

This application claims the benefit of U.S. Provisional Patent Application No. 63/691,749, filed on Sep. 6, 2024, the disclosure of which is incorporated by reference herein.

### BACKGROUND OF THE INVENTION

The desire for high-performance computing and networking is ubiquitous and seemingly ever-present. Prominent applications include data center servers, high-performance computing clusters, artificial neural networks, and network switches.

For decades, dramatic integrated circuit performance and cost improvements were driven by shrinking transistor dimensions combined with increasing die sizes, summarized in the famous Moore's Law. Transistor counts in the billions have allowed consolidation onto a single system-on-a-chip (SoC) of functionality that was previously fragmented across multiple ICs. However, the benefits of further transistor shrinks are decreasing dramatically as decreasing marginal performance benefits combine with decreased yields and increased per transistor costs.

Data communications between chips, boards, and server racks has also increasingly become a chokepoint in computer system design. Increased integrated circuit performance allows for processing of large amounts of data, which often is to be shared between chip, boards, and server racks. The sharing of this data using electrical data pathways may be problematic for a variety of reasons. For example, the propagation of the data may result in undesirably high power consumption. Also, for example, the propagation of the data over a length greater than, for example, one meter may not be feasible at desired data rates.

The sharing of data using optical pathways may also pose difficulties. Lasers, for example Distributed Feedback (DFB) lasers or vertical cavity side emitting lasers (VCSELs) may require undesirably high power levels, may not have desired reliability characteristics in a high heat environment, and may not be cost effective for relatively short length (e.g., less than 10 meters) high data rate transmissions. The use of LEDs for data communications between chips has also been proposed, but received light generated by LEDs at high data rates may be lower than desired, for example for optical pathways over 1 meter, or 5 meters.

### BRIEF SUMMARY OF THE INVENTION

An optical interconnect may include an array of microLEDs driven to generate light based on data and/or clock signals, an array of photodetectors to receive the light and generate electrical signals corresponding to the data and/or clock signals, and an optical transmission medium providing at least part of a pathway between the microLEDs and the photodetectors. The optical transmission medium may be an optical fiber bundle. In some embodiments a reflector structure for each of the microLEDs assists in coupling light from the microLEDs into fibers of the optical fiber bundle. In some embodiments a reflector structure for each of some of the microLEDs assists in coupling light from the each of the some of the microLEDs into fibers of the optical fiber bundle. In some embodiments a reflector structure for each of a plurality of microLEDs assists in coupling light from the each of the plurality of microLEDs into fibers of the optical fiber bundle. The reflector structure may be in the form of a compound parabolic concentrator (CPC).

Some embodiments in accordance with aspects of the invention provide an microLED-based optical interconnect, comprising: a plurality of microLEDs on a substrate; a plurality of reflector structures on or above the substrate, the reflector structures in the form of compound parabolic concentrators; and fibers of an optical fiber bundle on or above the reflector structures; with the reflector structures and fibers positioned for the reflector structures to direct light from the microLEDs into the fibers. In some embodiments the reflector structures are on the substrate. In some embodiments the reflector structures define a volume, and the volume is filled with epoxy. In some embodiments the fibers of the optical fiber bundle are embedded in the epoxy. In some embodiments there is a reflector structure for each microLED. In some embodiments there is one reflector structure for each of a plurality of the microLEDs. In some embodiments there is one fiber for each reflector structure. In some embodiments there are no lenses in an optical pathway between the microLEDs and the fibers.

In some aspects, a microLED-based optical interconnect comprises: a plurality of microLEDs on a substrate; for each of the microLEDs, a drive circuit to drive the microLEDs to generate light based on clock and/or data signals; a plurality of reflector structures on or above the substrate, the reflector structures each in the form of a compound parabolic concentrators, with a reflector structure for each microLED, each reflector structure defining a volume, the volume filled with epoxy and the microLED for the reflector structure; fibers of an optical fiber bundle on or above the reflector structures; with the reflector structures and fibers positioned for the reflector structures to direct light from the microLEDs into the fibers, with light from each microLED directed into a single corresponding fiber; a plurality of photodetectors, each of the photodetectors positioned to receive light from a single corresponding fiber; and for each of the photodetectors, receiver circuitry for processing an electrical signal generated by the photodetectors.

In some such aspects radial coordinates of each reflector structure is defined by positive real roots of an equation of the form C²r²+2(CSz+aP²)r+(z²S²−2aCQz−a²PT)=0, where a is the radial aperture, C=cos(theta), S=sin(theta), P=1+S, Q=1+P, T=1+Q, z is the height above the base, and theta is the maximum acceptance angle. In some such aspects the maximum acceptance angle is scaled using Snell's law. In some such aspects the microLEDs have a diameter less than 20 um. In some such aspects the microLEDs have a diameter less than 10 um. In some such aspects the microLEDs have a diameter between 6 um to 8 um, inclusive. In some such aspects the microLEDs are on centers between 40 um to 60 um. In some such aspects the optical fibers are multimode optical fibers. In some such aspects the optical fibers are arranged in a fiber bundle. In some such aspects the fiber bundle is a coherent fiber bundle. In some such aspects the reflector structures are on the substrate. In some such aspects the fibers of the optical fiber bundle are embedded in the epoxy. In some such aspects there are no lenses in an optical pathway between the microLEDs and the fibers.

These and other aspects of the invention are more fully comprehended upon review of this disclosure.

### BRIEF DESCRIPTION OF THE FIGURES

FIG. 1 is a block diagram of an optical interconnect, in accordance with aspects of the invention.

FIG. 2 is a block diagram of a parallel optical interconnect, in accordance with aspects of the invention.

FIGS. 3A-C illustrate views of a plurality of compound parabolic reflector structures, in accordance with aspects of the invention.

FIG. 4 illustrates a fabrication process flow for providing reflector structures for microLED-based optical interconnects, in accordance with aspects of the invention.

FIG. 5 is a cross-section of an embodiment of a reflector structure for a microLED, in accordance with aspects of the invention.

### DETAILED DESCRIPTION

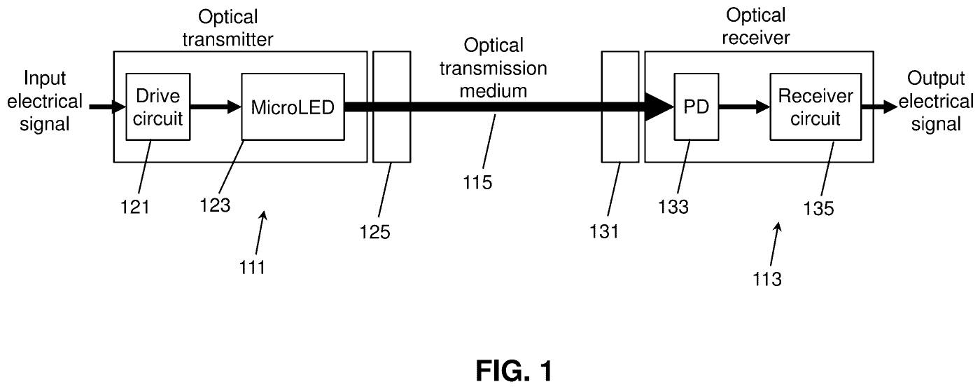

FIG. 1 is a block diagram of a communication channel of a parallel microLED optical interconnect. The communication channel includes an optical transmitter 111 coupled to an optical receiver 113 by a transmission medium 115. The optical transmitter includes at least one microLED 123 to generate light. In some embodiments the communication channel includes a single microLED, and for convenience the discussion herein will generally refer to a channel having a single microLED. In some embodiments, however, the communication channel may include a plurality of microLEDs, for example commonly driven to produce light.

The microLED is driven to produce light by a drive circuit 121. The drive circuit produces a microLED drive signal to drive the microLED. The drive circuit may receive electrical signals, for example clock and/or data signals, and generate the drive signal based on the clock and/or data signals. In most embodiments, the drive signal causes the microLED to generate light signals corresponding to the clock and/or data signals.

The light from the microLED is coupled into the transmission medium by input coupling optics 125. The input coupling optics comprises a reflector structure that couples light into the optical medium. In some embodiments the input coupling optics consists of the reflector structure. In some embodiments the input coupling optics consists of the reflector structure and material filling a volume defined by the reflector structure. In some embodiments the input coupling optics consists of the reflector structure, material filling a volume defined by the reflector structure, and material bonding ends of fibers to the material filling a volume of the reflector structure. In some embodiments the reflector structure is parabolic, with the microLED at or about a base of the parabolic structure. In some embodiments the parabolic reflector structure is paraboloid. In some embodiments the reflector structure comprises a wall with a partial parabolic cross section. In some embodiments a cross-section through a vertical (with a light source considered to be at a vertical bottom and a transmission medium at a vertical top) center line of the reflector structure provides opposing walls, each with a partial parabolic shape. In some embodiments the reflector structure is in a form of a compound parabolic concentrator.

In some embodiments the optical transmission medium is an optical fiber. In some embodiments the transmission medium is a plurality of optical fibers. In some embodiments the optical fiber is a single mode optical fiber. In some embodiments the optical fiber is a multimode optical fiber. In some embodiments the optical fiber is a fiber in a fiber bundle. In some embodiments the fiber bundle is a coherent imaging fiber bundle. In some embodiments the optical fiber is a fiber in a fiber sub-bundle. In some embodiments the fiber sub-bundle is a coherent imaging fiber sub-bundle.

Light from the transmission medium is coupled into the optical receiver 113 by output coupling optics 131. In some embodiments the output coupling optics comprises, or in some embodiments consists of, a reflector structure as discussed with respect to the input coupling optics. In some embodiments the output coupling optics may include one or more lenses.

The optical receiver includes a photodetector 133 and associated receiver circuitry 135. The photodetector receives light, generated by the microLED and passed through the transmission medium. The photodetector generates an electrical signal indicative of the received light. The electrical signal is processed by the receiver circuitry. In some embodiments the receiver circuitry includes transimpedance amplifiers (TIAs) and other signal processing circuitry that may be generally found in receiver circuitry for optical receivers.

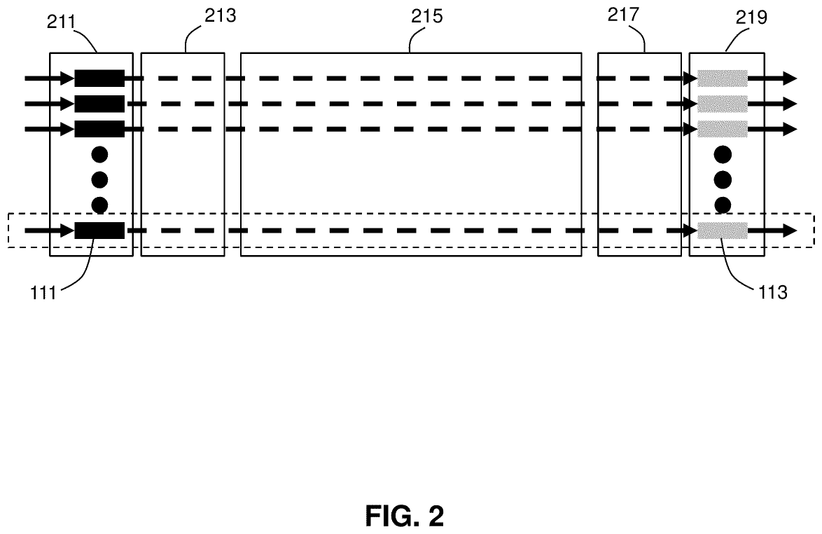

FIG. 2 is a block diagram of an embodiment of a parallel optical interconnect. A parallel optical interconnect comprises multiple parallel optical interconnect channels. Each of the channels may be provided by the communication channel of FIG. 1, for example. In some embodiments, the parallel optical interconnect includes an optical transmitter array 211. The optical transmitter array may comprise a plurality of optical transmitters 111. Each optical transmitter may be as discussed with respect to the communication channel of FIG. 1.

In some embodiments emitters of the optical transmitters are arranged in a regular grid. In some embodiments the emitters are microLEDs. In some embodiments the regular grid is a close-packed grid. In some embodiments the regular grid is a square or rectangular grid, and some embodiments the regular grid is a hexagonal grid, all of which may be close-packed grids. In some embodiments the microLEDs are on 50 um centers, or are on centers between 40 um to 60 um. In some embodiments the microLEDs have a diameter of less than 20 um. In some embodiments the microLEDs have a diameter of less than 10 um. In some embodiments the microLEDs have a diameter between 6 um to 10 um, inclusive. In some embodiments the microLEDs have a diameter between 6 um to 8 um, inclusive.

The parallel optical interconnect also includes an input optical coupling assembly array 213. The input optical coupling assembly array may comprise a plurality of reflector structures. The reflector structures are positioned and configured to couple light from the optical transmitter array to a first end of a parallel optical transmission medium 215. The parallel optical transmission medium carries the light, or some of it, from the first end of the parallel optical transmission medium to a second end of the parallel optical transmission medium.

In some embodiments the parallel optical transmission medium comprises a plurality of optical fibers. In some embodiments there is a one-to-one correspondence between optical fibers and optical transmitters. In some embodiments there are a plurality of optical fibers for each optical transmitter. In some embodiments the optical fibers are multimode optical fibers. In some embodiments the optical fibers are arranged in a fiber bundle. In some embodiments the fiber bundle is a coherent fiber bundle. In some embodiments the fiber bundle is a sub-bundle of a fiber bundle that may include a plurality of sub-bundles.

An output optical coupling assembly array 217 couples light from a second end of the parallel optical transmission medium to an optical receiver array 219. In some embodiments the optical receiver array includes a plurality of optical receivers. In some embodiments the optical receivers each may be the optical receiver 113 as discussed with respect to FIG. 1.

In some embodiments the output optical coupling assembly array comprises a plurality of reflector structures. In some embodiments the output optical coupling assembly array consists of a plurality of reflector structures. In some embodiments the reflector structures may be as discussed herein. In some embodiments there is a one-to-one correspondence between reflector structures and optical receivers of the optical receiver array. In some embodiments the output optical coupling assembly array may include one or more lenses. In some embodiments one or more lenses may be associated with each optical receiver of the optical receiver array.

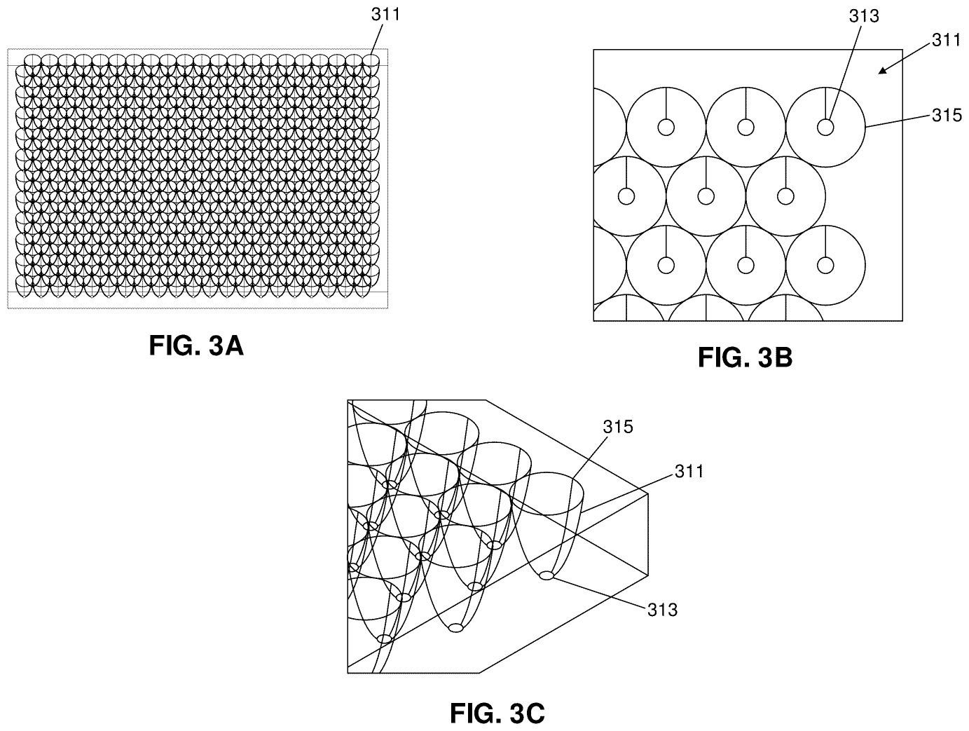

FIG. 3A is a top view of an example array of reflector structures. The reflector structures are in a substrate. In some embodiments the array of reflector structures provides the input optical coupling assembly array of the embodiment discussed with respect to FIG. 2. In some embodiments the array of reflector structures provides the output optical coupling assembly array of the embodiment discussed with respect to FIG. 2.

The array of reflector structures includes a plurality of reflector structures, including for example reflector structure 311. In the embodiment of FIG. 3A, the reflector structures are shown arranged in a rectangular close-packed grid.

FIG. 3B is a close-up top view of the reflector structure 311, along with nearby reflector structures. In the close-up view, it may be seen that the reflector structure forms an upper circular opening 315. A lower circular opening 313 is concentrically centered within the upper circular opening. A sidewall couples the upper circular opening and the lower circular opening. In some embodiments the sidewall may have a cross-section having a shape corresponding to a segment of a parabola. In some embodiments the sidewall may have a cross-section having a shape corresponding to a plurality of segments of a parabola.

FIG. 3C is an isometric close-up view of the reflector structure 311, along with nearby reflector structures. In FIG. 3C, the lower circular opening 313 is at a bottom of the substrate. The sidewall 317 extends upwardly from the circumference of the lower circular opening to the circumference of the upper circular opening 315. In some embodiments the shape of the sidewall conforms to a segment of a parabola. In some embodiments the sidewall provides a compound parabolic reflector. In some embodiments the diameter of the lower circular opening is sized to allow for insertion of a microLED through the lower circular opening. In some embodiments the diameter of the lower circular opening is sufficient to practically allow for insertion of a microLED through the lower circular opening, but not greater. In some embodiments the diameter of the lower circular opening is no more than 2 um greater than a longest cross-sectional chord of a microLED placed in or inserted through the lower circular opening. In some embodiments the diameter of the lower circular opening is no more than 4 um greater than a longest cross-sectional chord of a microLED placed in or inserted through the lower circular opening. In some embodiments the diameter of the lower circular opening is no more than 6 um greater than a longest cross-sectional chord of a microLED placed in or inserted through the lower circular opening. In some embodiments a diameter of the upper circular opening is dependent on diameter of the lower circular opening and a height of the sidewall.

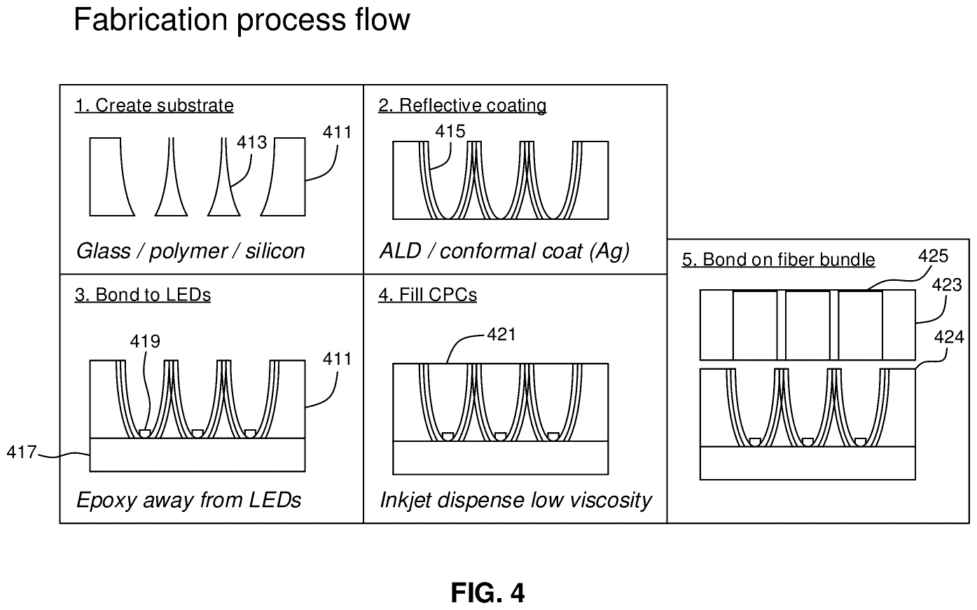

FIG. 4 illustrates a fabrication process flow providing reflector structures. In some embodiments the fabrication process flow provides reflector structures for microLED-based optical interconnects. In some embodiments the fabrication process flow provides an input optical coupling array for microLED-based optical interconnects. In some embodiments the fabrication process flow provides an optical transmitter array and an input optical coupling array for microLED-based optical interconnects. In some embodiments the fabrication process flow provides a microLED-based optical transmitter array bonded to an input optical coupling array comprising reflector structures bonded to a fiber bundle. In some embodiments the fabrication process flow provides a microLED-based optical transmitter array bonded to an input optical coupling array consisting of reflector structures bonded to a fiber bundle. In some embodiments the reflector structures comprise reflector structures in the form of compound parabolic concentrators. In some embodiments the reflector structures consist of reflector structures in the form of compound parabolic concentrators.

In block 1 of the fabrication process flow, the process forms a shaped substrate. In some embodiments the shaped substrate is formed by removing material from a square or rectangular cuboid substrate 411 (e.g., a flat substrate). The removed material forms structures in the shape of a reflector structure. The shape of the reflector structure forms apertures through the substrate 411, with a wall 413 of the aperture (walls of the aperture, as shown in the cross-section shown in FIG. 4) extending from a bottom of the substrate 411 to a top of the substrate 411. In some embodiments the shape of the reflector structure is in the shape of one or more parabolic segments. In some embodiments the shape of the reflector structure is in the shape of a compound parabolic concentrator. In some embodiments the shape of the reflector structure is a shape such as discussed with respect to the reflector structure 311 of FIGS. 3A-C. In some embodiments the material is removed by way of etching. In some embodiments the substrate is a glass substrate. In some embodiments the substrate is a polymeric substrate. In some embodiments the substrate is a silicon substrate.

In block 2 of the fabrication process flow, the process forms a reflective coating on surfaces of the shapes of the reflector structures. In some embodiments the reflective coating is a conformal coating. In some embodiments the reflective coating is formed using atomic layer depositioning. In some embodiments the reflective coating is a gold coating. In some embodiments the reflective coating is an aluminum coating. The shapes of the reflector structures coated with the reflective coating forms reflector structures.

In block 3 of the fabrication process flow, the process bonds the shaped substrate 411 including the reflector structures to a substrate 417 with microLEDs 419 on a surface of the substrate. In some embodiments the bottom of the shaped substrate is bonded to a top surface of the substrate. In some embodiments the shaped substrate is bonded to the substrate in a position relative to the substrate such that the microLEDs are in the apertures of the shaped substrate. In some embodiments the shaped substrate is bonded to the substrate in a position relative to the substrate such that light emitted by the microLEDs travels into or through the apertures, or at least some light emitted by the microLEDs travels into or through the apertures. In some embodiments the shaped substrate is bonded to the substrate in a position relative to the substrate such that at least some light emitted by the microLEDs reflects from walls of the apertures. In some embodiments the shaped substrate is bonded to the substrate using epoxy. In some embodiments the epoxy is applied to areas of the substrate away from the microLEDs and/or to areas of the shaped substrate that will be away from the microLEDs.

In block 4 of the fabrication process flow, interiors of the reflector structures are filled. In some embodiments the interiors of the reflector structures are filled with an epoxy. In some embodiments the epoxy is a low viscosity epoxy. In some embodiments the reflector structures are filled using an inkjet. In some embodiments the interiors are filled with a material that has a same index of refraction as a core of an optical fiber. In some embodiments the epoxy has a same index of refraction as a core of an optical fiber. In some embodiments the interiors are filled using an inkjet. In some embodiments the interiors are sufficiently filled so that no air gaps are present in the interiors. In some embodiments the interiors are sufficiently filled such that the interiors do not have air gaps would be expected to be a cause of device failure upon heating of a device including the reflector structures, for example as part of bonding or otherwise combining of structures of a microLED optical interconnect.

In block 5 of the fabrication process flow, a fiber bundle 423 is bonded to the shaped substrate including the filled reflector structures. In some embodiments an end of the fiber bundle is bonded to a top of the shaped substrate 411 including the filled reflector structures. In some embodiments the fiber bundle is bonded using an epoxy 424. In some embodiments the epoxy is the same epoxy as used to fill the reflector structures. In some embodiments the epoxy has a same index of refraction as material used to fill the reflector structures. In some embodiments fibers 425 of the fiber bundle are positioned over tops of the reflector structures, so as to receive light emitted by the microLEDs in or below the reflector structures. In some embodiments a layer of epoxy on a top surface of the substrate including the filled reflector structures separates the substrate and the fiber bundle.

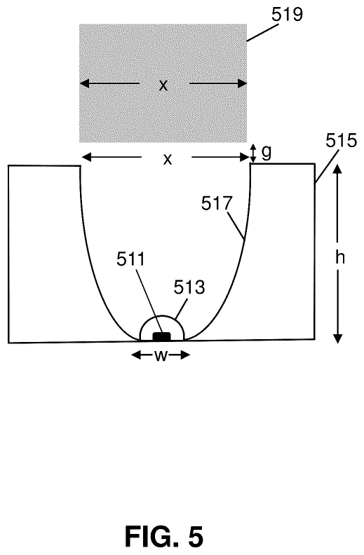

FIG. 5 is a cross-section of an embodiment of a reflector structure for a microLED. The embodiment shown in FIG. 5 is that of a CPC reflector. In some embodiments the CPC reflector is as discussed in High Collection Nonimaging Optics, W. T. Welford and R. Winston (1989), the disclosure of which is incorporated by reference herein for all purposes. In some embodiments the CPC reflector is a Basic CPC as discussed in High Collection Nonimaging Optics, W. T. Welford and R. Winston (1989). The CPC reflector is formed in a substrate 515. The substrate includes an aperture forming the shape of the CPC reflector. The aperture forms circular openings in both a lower surface of the substrate and an upper surface of the substrate, with the circular opening in the lower surface being smaller in radius than the circular opening in the upper surface. The aperture also forms a parabolic surface 517 extending between edges of the circular openings. The parabolic surface has a reflective surface, for example as discussed above.

In FIG. 5 a microLED 511 is shown as inserted into the lower circular opening, and an end of an optical fiber 519 is shown above the upper circular opening. A core of the optical fiber may have a same radial dimension as that of the upper circular opening. In some embodiments the upper circular opening has a same radial dimension as the optical fiber. In some embodiments the upper circular opening has a diameter of 44 microns. In some embodiments there may be a gap g between the optical fiber and a top surface of the substrate of the CPC reflector. In some embodiments the gap may be filled with epoxy fixing the optical fiber in place with respect to the substrate. In some embodiments the epoxy may have a same index of refraction at wavelengths of interest as that of material filling the volume of the CPC reflector. In some embodiments, and as shown in FIG. 5, the microLED may be surrounded by an encapsulant, for example a semi-spherical encapsulant. The encapsulant may have a same index of refraction about wavelength(s) of interest as that of material which may be used to fill a volume of the CPC reflector.

In some embodiments the CPC reflector is defined by three parameters: radius of the smaller aperture, maximum acceptance angle theta, and length. In FIG. 5, the radius of the smaller aperture is shown as w and the length (or height) of the reflector is that of the substrate, shown as h. The maximum acceptance angle, in some embodiments, is scaled using Snell's law to take into account material filling the volume of the CPC reflector.

In some embodiments, radial coordinates r of the parabolic surface may be determined by positive real roots of

$${C}^{2} {r}^{2} + 2 ( CSz + {aP}^{2} ) r + ( {z}^{2} {S}^{2} - 2 aCQz - {a}^{2} PT ) = 0 \qquad ( 1 )$$

where a is the radial aperture, C=cos(theta), S=sin(theta), P=1+S, Q=1+P, T=1+Q, z is the height above the base, and theta is the maximum acceptance angle (in some embodiments scaled using Snell's law as discussed above).

In some embodiments the maximum acceptance angle may be 25 degrees, the radius of the smaller aperture may be 10 microns, and the height of the reflector may be 35 microns. In some embodiments the maximum acceptance angle may be between 12 and 30 degrees, the radius of the smaller opening may be between 8 and 15 microns, and the height of the reflector may be 20 and 100 microns. In some embodiments the maximum acceptance angle is between 18 and 28 degrees. In some embodiments the radius of the smaller opening is between 6 and 12 microns and the maximum acceptance angle is between 12 and 28 degrees, or between 16 and 28 degrees in some embodiments, and the height of the reflector is at least 30 microns, or at least 40 microns in some embodiments.

In FIG. 5, the optical fiber is shown as having a numerical aperture of 0.2. In some embodiments the optical fiber may have either a smaller or a larger numerical aperture. In some embodiments the numerical aperture may be 0.3 or greater. In some embodiments the numerical aperture may be 0.4 or greater. In some embodiments the numerical aperture may be between 0.2 and 0.45. In general, increasing the numerical aperture may increase coupling efficiency of light into the optical fiber. However, in some embodiments the rate of increase in coupling efficiency with increase in numerical aperture may slow for numerical apertures above 0.34, and may be effectively unimportant for numerical apertures above 0.42 or 0.45.

Although the invention has been discussed with respect to various embodiments, it should be recognized that the invention comprises the novel and non-obvious claims supported by this disclosure.

What is claimed is:

1. A microLED-based optical interconnect, comprising:
a plurality of microLEDs on a substrate;
for each of the microLEDs, a drive circuit to drive the microLEDs to generate light based on clock and/or data signals;
a plurality of reflector structures on or above the substrate, the reflector structures each in the form of a compound parabolic concentrators, with a reflector structure for each microLED, each reflector structure defining a volume, the volume filled with epoxy and the microLED for the reflector structure;
fibers of an optical fiber bundle on or above the reflector structures;
with the reflector structures and fibers positioned for the reflector structures to direct light from the microLEDs into the fibers, with light from each microLED directed into a single corresponding fiber;
a plurality of photodetectors, each of the photodetectors positioned to receive light from a single corresponding fiber; and
for each of the photodetectors, receiver circuitry for processing an electrical signal generated by the photodetectors.

2. The microLED-based optical interconnect of claim 1, wherein radial coordinates of each reflector structure is defined by positive real roots of an equation of the form C²r²+2(CSz+aP²)r+(z²S²−2aCQz−a²PT)=0, where a is the radial aperture, C=cos(theta), S=sin(theta), P=1+S, Q=1+P, T=1+Q, z is the height above the base, and theta is the maximum acceptance angle.

3. The microLED-based optical interconnect of claim 2, wherein the maximum acceptance angle is scaled using Snell's law.

4. The microLED-based optical interconnect of claim 1, wherein the microLEDs have a diameter less than 20 um.

5. The microLED-based optical interconnect of claim 1, wherein the microLEDs have a diameter less than 10 um.

6. The microLED-based optical interconnect of claim 1, wherein the microLEDs have a diameter between 6 um to 8 um, inclusive.

7. The microLED-based optical interconnect of claim 1, wherein the microLEDs are on centers between 40 um to 60 um.

8. The microLED-based optical interconnect of claim 1, wherein the optical fibers are multimode optical fibers.

9. The microLED-based optical interconnect of claim 1, wherein the optical fibers are arranged in a fiber bundle.

10. The microLED-based optical interconnect of claim 1, wherein the fiber bundle is a coherent fiber bundle.

11. The microLED-based optical interconnect of claim 1, wherein the reflector structures are on the substrate.

12. The microLED-based optical interconnect of claim 1, wherein the fibers of the optical fiber bundle are embedded in the epoxy.

13. The microLED-based optical interconnect of claim 1, wherein there are no lenses in an optical pathway between the microLEDs and the fibers.
